(19) United States
(12) Patent Application Publication
(10) Pub. No.: US 2025/0132211 A1
(43) Pub. Date: Apr. 24, 2025

(54) Semiconductor Device and Method of Forming Flexible Encapsulant Over Thin Electrical Component

(71) Applicant: JCET STATS ChipPAC Korea Limited, Incheon (KR)

(72) Inventor: YeoJun Yun, Incheon (KR)

(73) Assignee: JCET STATS ChipPAC Korea Limited, Incheon (KR)

(21) Appl. No.: 18/493,543

(22) Filed: Oct. 24, 2023

(51) Int. Cl. H01L 23/29; H01L 21/56; H01L 21/768; H01L 23/31; H01L 23/538

(52) U.S. Cl. CPC H01L 23/293; H01L 21/56; H01L 21/76898; H01L 23/3128; H01L 23/5386

(57) ABSTRACT

A semiconductor device has a first electrical component and a flexible encapsulant disposed over the first electrical component. The first electrical component is reduced in thickness while in wafer form. The first electrical component has a thickness of 400 micrometers. The first electrical component is attached to a substrate to provide a base to deposit the flexible encapsulant. An interconnect structure is formed over the first electrical component. The flexible encapsulant can be made from polyimide, thermoplastic elastomer, thermoplastic vulcanizate, thermoplastic urethane, or polyvinyl chloride. The interconnect structure has an insulating layer formed over the first electrical component, and a conductive layer formed over the insulating layer as an RDL. A bump can be formed over the conductive layer. The flexible encapsulant can be disposed over a second electrical component. The second electrical component may have a different electrical function from the first electrical component.

### FIELD OF THE INVENTION

The present invention relates in general to semiconductor devices and, more particularly, to a semiconductor device and method of forming a flexible encapsulant over a thin and flexible electrical component.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain a semiconductor die or substrate with electrical interconnect structures formed over one or more surfaces of the semiconductor die or substrate to perform necessary electrical functions. A plurality of bumps is formed on the surface of the semiconductor die or substrate for external interconnect.

Advanced packaging process technology for implementing high-intensity devices that meet low-power and high-performance driving conditions is central, facing limitations in performance generation methods due to scaling of semiconductor devices. However, conventional packaging technology includes a thick growth substrate in the device itself, limiting heat dissipation and electrical conduction of the chip. In addition, its utilization is limited due to lack of flexibility, originating from growth substrate.

### BRIEF DESCRIPTION OF THE DRAWINGS

FIGS. 1a-1k illustrate a semiconductor wafer bonded to a temporary substrate and singulated;

FIGS. 2a-2j illustrate a process of forming a flexible encapsulant over thin electrical components;

FIGS. 3a-3b illustrate the flexible semiconductor package with a flexible encapsulant over a thin electrical component;

FIGS. 4a-4f illustrate another process of forming a flexible encapsulant over thin dissimilar electrical components;

FIGS. 5a-5b illustrate the flexible semiconductor package with a flexible encapsulant over thin dissimilar electrical components; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

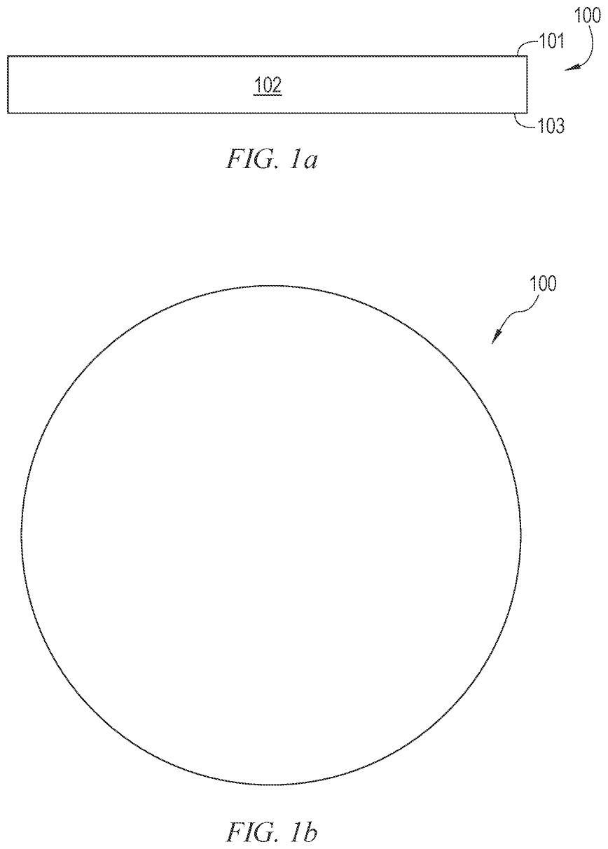

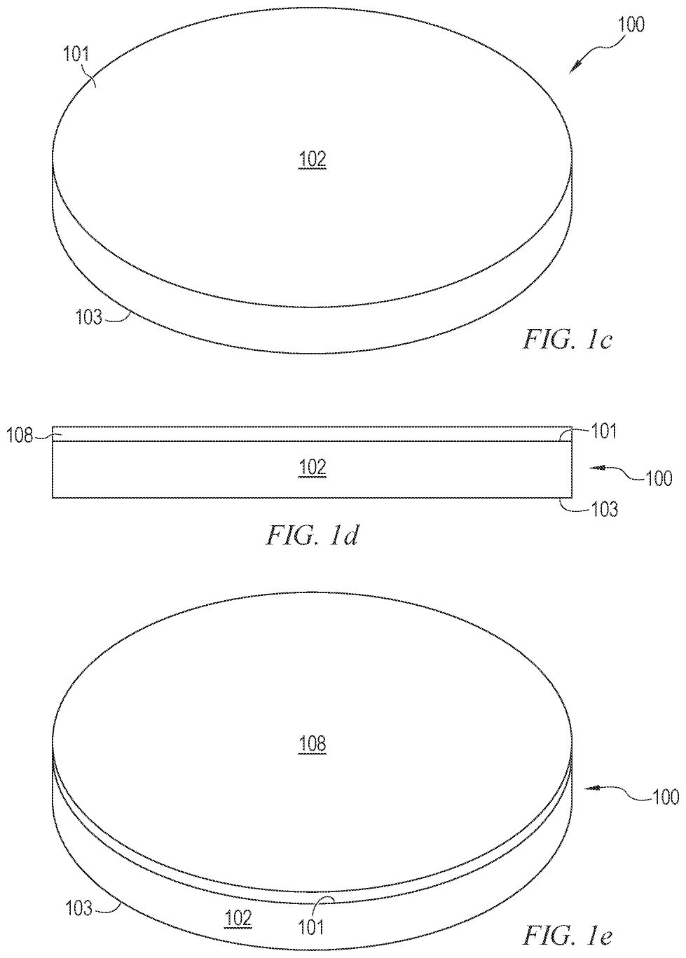

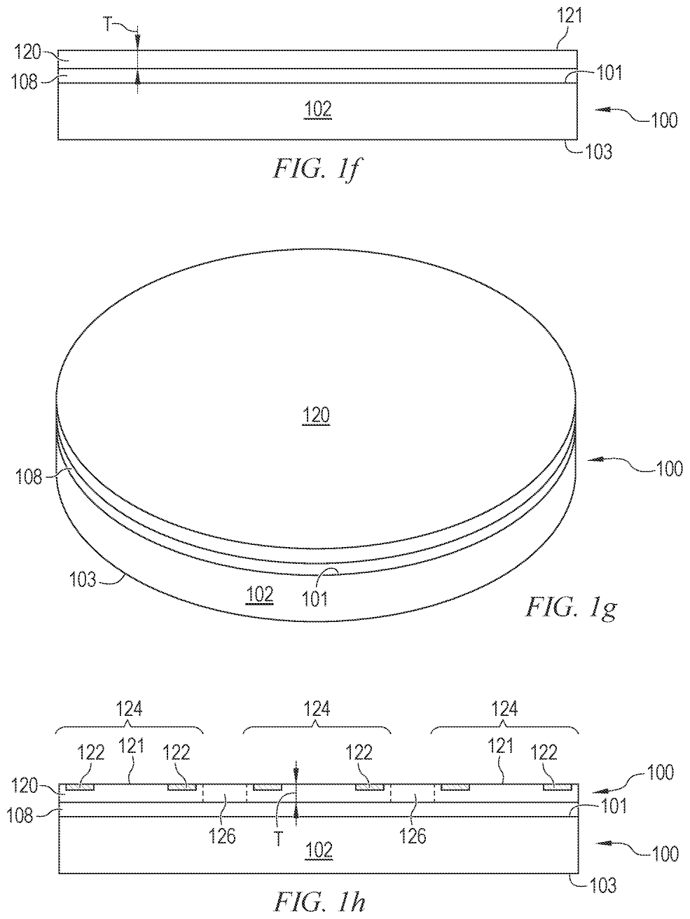

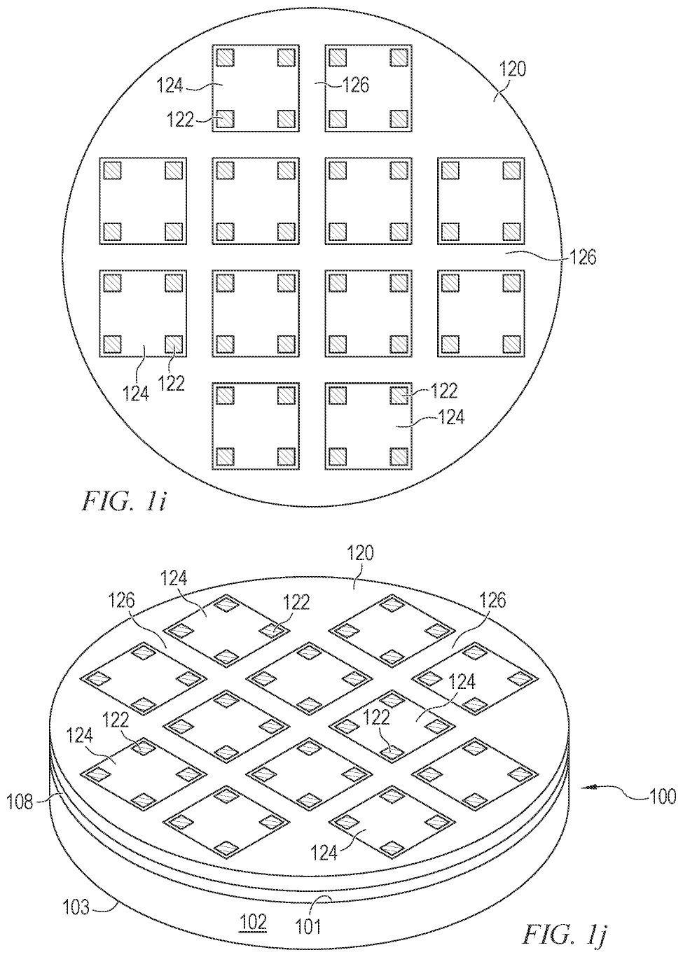

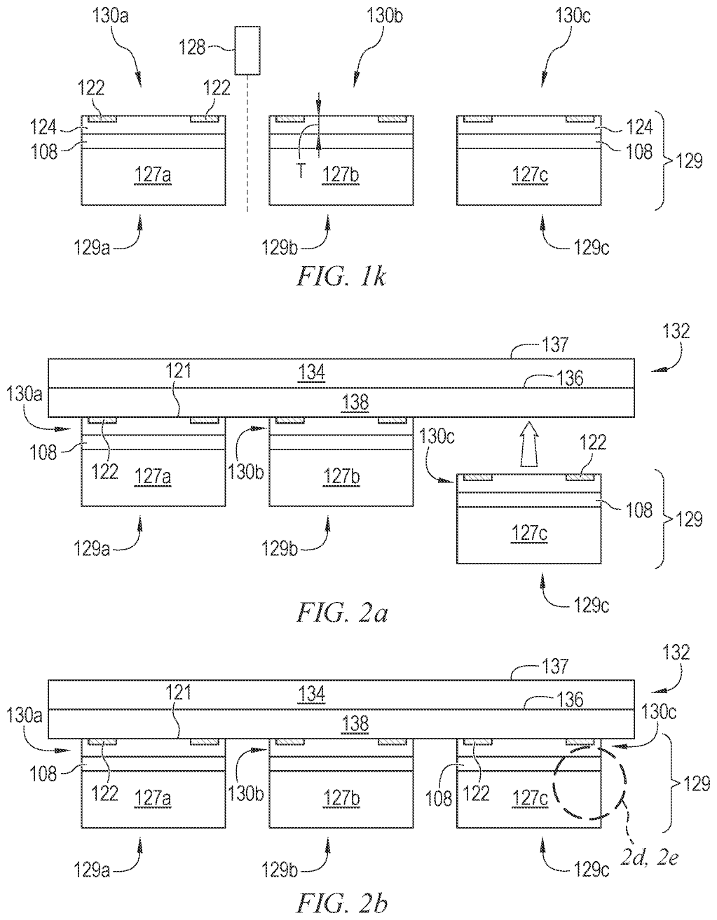

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. Semiconductor wafer 100 has major surface 101 and major surface 103, opposite major surface 101. FIG. 1b is a top view of a circular semiconductor wafer 100. Semiconductor wafer 100 can also be rectangular or other geometrical shape. In one embodiment, semiconductor wafer 100 has a width or diameter of 100-450 millimeters (mm). FIG. 1c is a perspective view of circular semiconductor wafer 100.

In FIG. 1d, a temporary sacrificial or protective layer 108 is formed over surface 101 of semiconductor wafer 100. In one embodiment, sacrificial layer 108 is epitaxially grown on surface 101. FIG. 1e is a perspective view of sacrificial layer 108 formed over surface 101 of semiconductor wafer 100. Sacrificial layer 108 can be a etch-stop layer made of aluminum arsenic (AlAs), aluminum gallium arsenic (AlGaAs), indium gallium phosphorus (InGaP), or aluminum indium phosphorus (AlInP).

In FIG. 1f, semiconductor layer 120 is formed over sacrificial layer 108 with a thickness T of 400 micrometers (μm). In one embodiment, semiconductor layer 120 is epitaxially grown on sacrificial layer 108. Semiconductor layer 120 can be silicon, germanium, aluminum phosphide, aluminum arsenide, gallium arsenide, gallium nitride, indium phosphide, silicon carbide, or other material suitable to form active semiconductor devices, as well as metallization patterns. FIG. 1g is a perspective view of semiconductor layer 120 formed over sacrificial layer 108.

In FIG. 1h, surface 121 of semiconductor layer 120 is subject to various front-end manufacturing processes, such as deposition, implantation, photolithography, and etching, to form a plurality of semiconductor die or electrical components 124 separated by a non-active, inter-die wafer area or saw streets 126. Each semiconductor die 124 has an active surface 121 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 121 to implement analog circuits or digital circuits, such as digital signal processor (DSP), application specific integrated circuits (ASIC), memory, or other signal processing circuit. Semiconductor die 124 may also contain IPDs, such as inductors, capacitors, and resistors, for RF signal processing. Accordingly, semiconductor layer 120 is an active semiconductor layer.

An electrically conductive layer 122 is formed over active surface 121 using PVD, CVD, electrolytic plating, electroless plating process, or other suitable metal deposition process. Conductive layer 122 can be one or more layers of aluminum (Al), copper (Cu), tin (Sn), nickel (Ni), gold (Au), silver (Ag), or other suitable electrically conductive material. Conductive layer 122 operates as contact pads electrically connected to the circuits on or within active semiconductor layer 120.

FIG. 1i is a top view of semiconductor die 124 formed in semiconductor layer 120 and separated by a non-active, inter-die wafer area or saw streets 126. Saw streets 126 provides cutting areas to singulate semiconductor layer 120 and semiconductor wafer 100 into individual semiconductor die 124, each with conductive layer 122. FIG. 1j is a perspective view of semiconductor layer 120 with active devices and metallization patterns formed over sacrificial layer 108.

In FIG. 1k, semiconductor wafer 100 and semiconductor layer 120 are singulated through saw street 126 using a saw blade or laser cutting tool 128 into individual semiconductor die 124. Semiconductor die 124 are thin and flexible with thickness T. The singulation also dices semiconductor wafer 100 into wafer units 127a-127c. The combination of wafer units 127a-127c, sacrificial layer 108, and semiconductor die 124 constitutes unit die 129, shown as unit die 129a-129c. The individual semiconductor die 124 can be inspected and electrically tested for identification of known good die or known good unit (KGD/KGU) post singulation.

More generally, semiconductor die 124 are designated as electrical components 130a-130c. Electrical components 130a-130c are thin and flexible, as described for semiconductor die 124. In one embodiment, electrical components 130a-130c each provide the same electrical function, in one semiconductor package. For example, electrical components 130a-130c can be power management integrated circuit (PMIC), graphical processing unit (GPU), central processing unit (CPU), accelerated processing unit (APU), or radio frequency (RF). Alternatively, electrical components 130a-130c each provide a different electrical function, in one semiconductor package. Electrical components 130a-130c can also include other semiconductor die, semiconductor packages, surface mount devices, RF components, discrete electrical devices, or integrated passive devices (IPD).

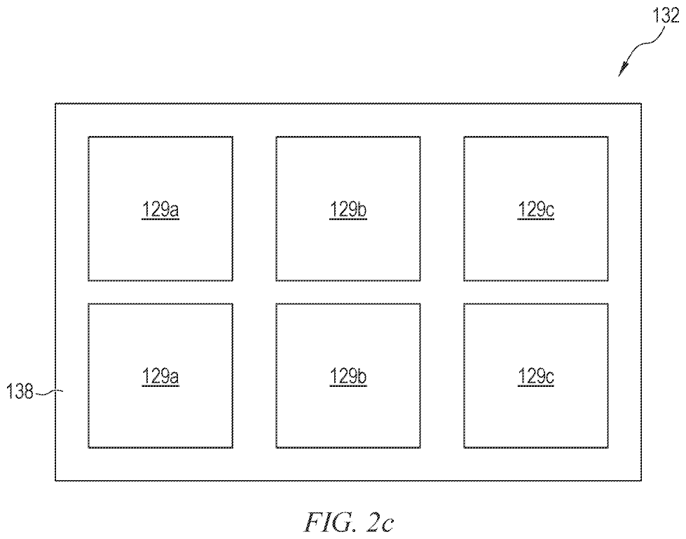

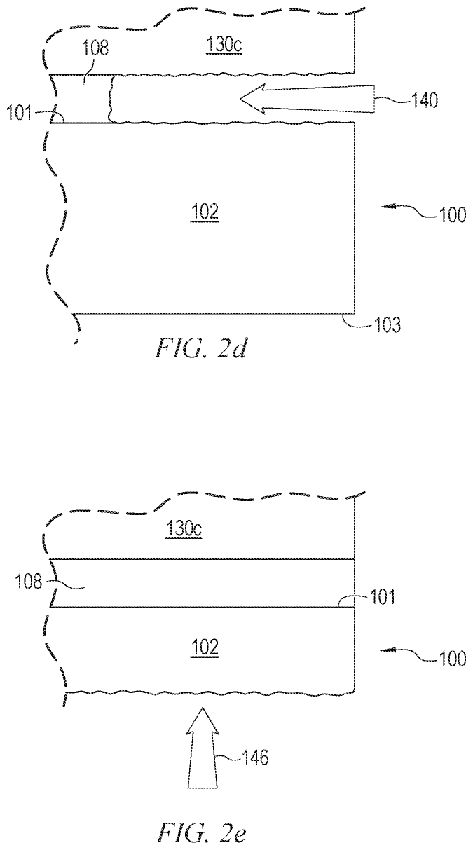

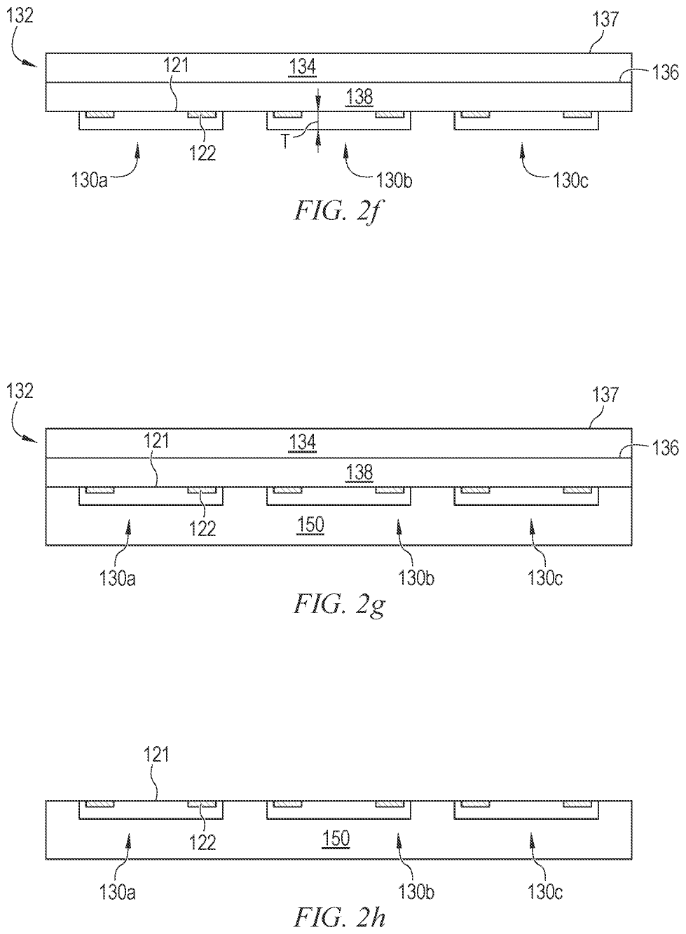

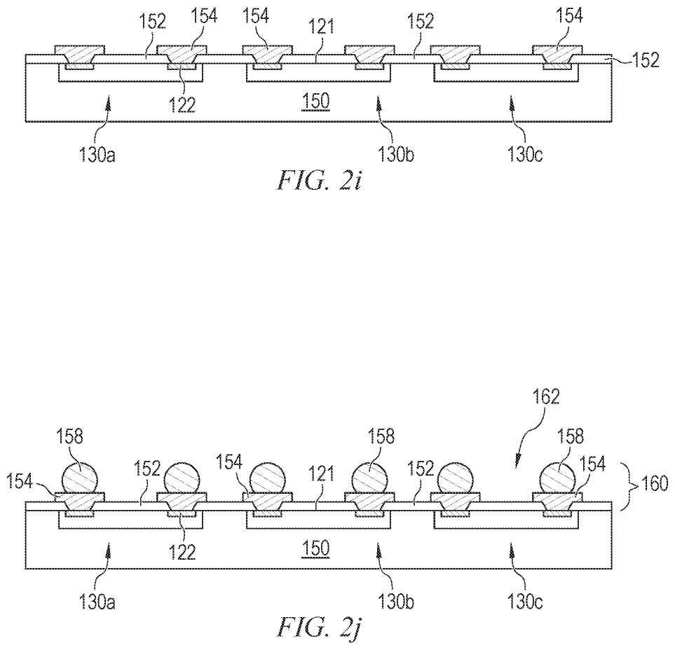

FIG. 2a illustrates a temporary substrate or carrier 132 containing sacrificial material 134, such as silicon, polymer, beryllium oxide, glass, or other suitable low-cost, rigid material for structural support. Substrate 132 has major surface 136 and major surface 137, opposite surface 136. Adhesive film 138 is disposed over surface 136 of carrier 132. Adhesive film 138 can be epoxy, silicone, polyimide, or other material suitable to securely hold electrical components 130a-130c in place.

Unit die 129a-129c, with respective electrical components 130a-130c, are positioned over adhesive film 138 using a pick and place operation with active surface 121 oriented toward the adhesive film. FIG. 2b shows unit die 129a-129c bonded to adhesive film 138 on substrate 132. FIG. 2c is a top view of unit die 129a-129c bonded to adhesive film 138 on substrate 132.

Wafer units 127a-127c and sacrificial layer 108 are next removed. In one embodiment, an etching process, such as hydrofluoric acid (HF) or other wet etchants, is applied to sacrificial layer 108, as shown in FIG. 2d and identified in FIG. 2b. Sacrificial layer 108 is removed in the lateral direction of arrow 140. Once sacrificial layer 108 is removed, wafer unit 127 will release. Sacrificial layer 108 should be removed without damage to electrical components 130a-130c. Alternatively, an etching process is applied to wafer unit 127, as shown in FIG. 2e and identified in FIG. 2b. Wafer unit 127 is removed in the vertical direction of arrow 146. Sacrificial layer 108 operates as an etch stop to prevent damage to electrical components 130a-130c. Sacrificial layer 108 can then be removed with a cleaning process. Substrate 120 can also be removed by chemical mechanical polishing (CMP), mechanical peel-off, mechanical grinding, thermal bake, ultra-violet (UV) light, or wet stripping. FIG. 2f shows electrical components 130a-130c attached to adhesive film 138, with sacrificial layer 108 and wafer units 127a-127c having been removed. The remaining electrical components 130a-130c are thin and flexible with a thickness T.

In FIG. 2g, encapsulant or molding compound 150 is deposited over and around electrical component 130a-130c and over adhesive film 138 using a paste printing, compressive molding, transfer molding, liquid encapsulant molding, vacuum lamination, spin coating, or other suitable applicator. Flexible encapsulant 150 is a flexible epoxy molding compound (EMC), such as polyimide, thermoplastic elastomer, thermoplastic vulcanizate, thermoplastic urethane, polyvinyl chloride, and other suitable flexible material. Flexible encapsulant 150 can be liquid or granular polymer composite material, such as a flexible resin with filler, flexible epoxy with filler, or flexible polymer with proper filler. Flexible encapsulant 150 is non-conductive, provides structural support, and environmentally protects the semiconductor device from external elements and contaminants.

In FIG. 2h, carrier 132 is removed by releasing adhesive film 138 with heat or UV light, leaving active surface 121 of electrical components 130a-130c exposed for electrical interconnect.

In FIG. 2i, insulating or passivation layer 152 is formed over conductive layer 122 and active surface 121 of electrical components 130a-130c using PVD, CVD, printing, lamination, spin coating, spray coating, sintering or thermal oxidation. Insulating layer 134 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Portions of insulating layer 152 are removed using an etching process or laser direct ablation (LDA) to form openings or vias extending to conductive layer 122 for further electrical interconnect.

A conductive layer 154 is formed over insulating layer 152 using PVD, CVD, electrolytic plating, electroless plating process, or other suitable metal deposition process. Conductive layer 154 can be one or more layers of Al, Cu, Sn, Ni, Au, Ag, or other suitable electrically conductive material. Portions of conductive layer 154 can be electrically common or electrically isolated depending on the design and function of electrical components attached thereto. Conductive layer 154 is a redistribution layer (RDL) as it redistributes the electrical signal across and over electrical components 130a-130c and flexible encapsulant 150.

In FIG. 2j, an electrically conductive bump material is deposited over conductive layer 154 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 154 using a suitable attachment or bonding process. In one embodiment, the bump material is reflowed by heating the material above its melting point to form balls or bumps 158. In one embodiment, bump 158 is formed over an under bump metallization (UBM) having a wetting layer, barrier layer, and adhesive layer. Bump 158 can also be compression bonded or thermocompression bonded to conductive layer 154. Bump 158 represents one type of interconnect structure that can be formed over conductive layer 154. The interconnect structure can also use bond wires, conductive paste, stud bump, micro bump, or other electrical interconnect.

The combination of insulating layer 152, conductive layer 154, and bumps 158 constitutes interconnect structure 160. Additional insulating layers like 152 and conductive layers like 154 can be formed as well to interconnect structure 160. The combination of electrical components 130a-130c, interconnect structure 160, and flexible encapsulant 150 constitute semiconductor package 162.

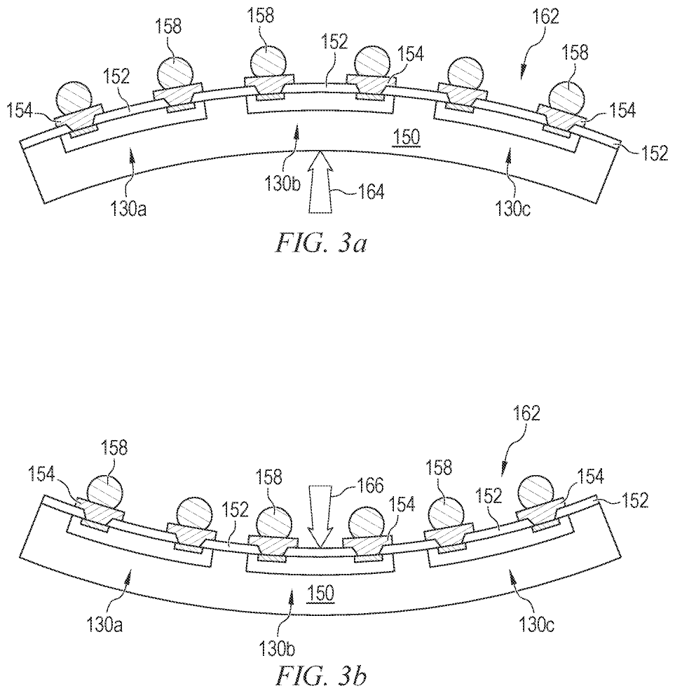

The flexible nature of encapsulant 150 allows semiconductor package 162 to bend and flex, as shown in FIGS. 3a-3b. As noted above, electrical components 130a-130c are thin and flexible. Flexible encapsulant 150 helps protect the thin and flexible electrical components 130a-130c. Semiconductor package 162 is convex in response to a force in the direction of arrow 164 due to the flexible nature of encapsulant 150, as in FIG. 3a. Semiconductor package 162 is concave in response to a force in the direction of arrow 166, as in FIG. 3b. Semiconductor package 162 is light weight, and the thin and flexible electrical components 130a-130c are efficient controlling of heat and electrical generation. Semiconductor package 162 is applicable to wearable devices, e.g., flexible displays.

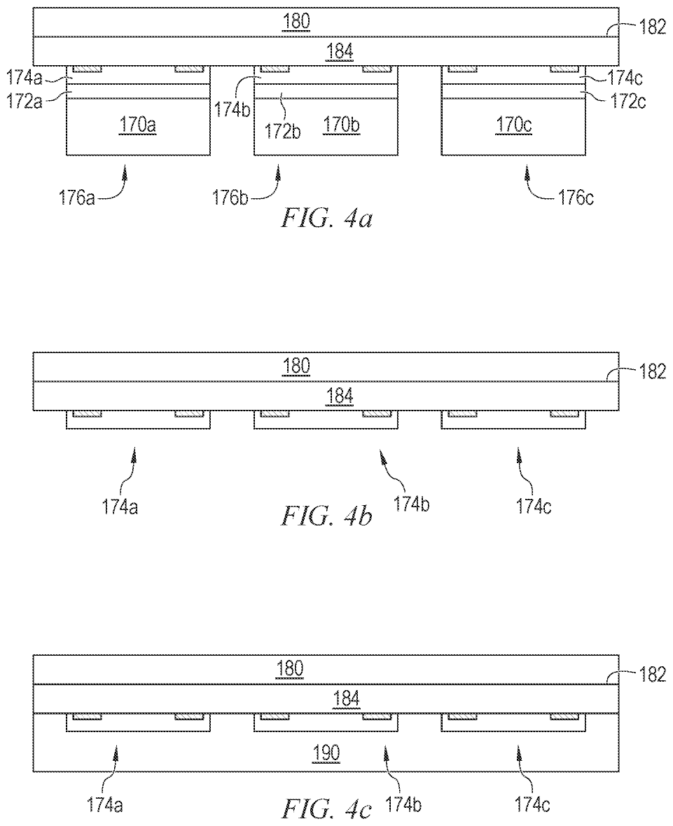

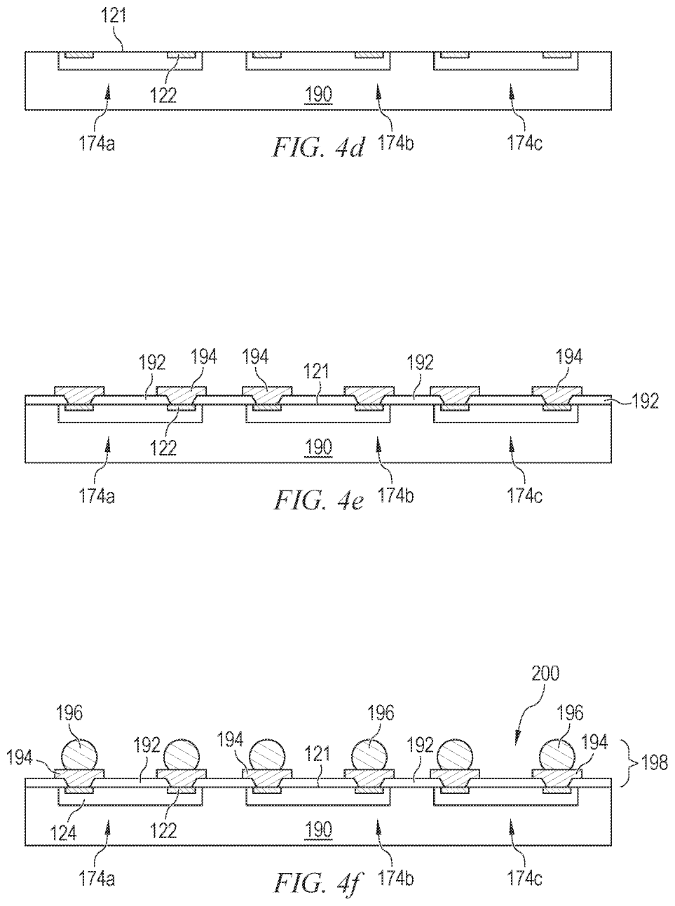

In another embodiment, continuing from FIG. 1k, FIG. 4a illustrates a plurality of wafer units 170a-170c, each containing silicon, germanium, aluminum phosphide, aluminum arsenide, gallium arsenide, gallium nitride, indium phosphide, silicon carbide, or other bulk material for structural support. Sacrificial or protective layers 172a-172b are formed over wafer units 170a-170c, respectively, similar to FIG. 1d. Sacrificial layers 172a-172c can be etch-stop layers made of AlAs, AlGaAs, InGaP, or AlInP.

Electrical components 174a-174c are formed over sacrificial layers 172a-172c and wafer units 170a-170c, similar to FIGS. la-1k. In one embodiment, electrical components 174a-174c each provide a different electrical function, in one semiconductor package. For example, electrical components 174a-174c can be PMIC, GPU, CPU, APU, and RF. Electrical components 174a-174c are thin and flexible, as described for semiconductor die 124. Alternatively, electrical components 174a-174c can include other semiconductor die, semiconductor packages, surface mount devices, RF components, discrete electrical devices, or IPD.

FIG. 4a further illustrates a temporary substrate or carrier 180 containing sacrificial material, such as silicon, polymer, beryllium oxide, glass, or other suitable low-cost, rigid material for structural support. Adhesive film 184 is disposed over surface 182 of carrier 180, similar to FIGS. 2a-2b. Adhesive film 184 can be epoxy, silicone, polyimide, or other material suitable to securely hold electrical components 174a-174c in place. The combination of wafer units 127a-172c, adhesive film 184, and electrical components 174a-174c constitute unit die 176a-176c.

In FIG. 4b, wafer units 170a-170c and sacrificial layers 172a-172c are removed, similar to FIG. 2d or 2e.

In FIG. 4c, encapsulant or molding compound 190 is deposited over and around electrical component 174a-174c and over adhesive film 184 using a paste printing, compressive molding, transfer molding, liquid encapsulant molding, vacuum lamination, spin coating, or other suitable applicator. Flexible encapsulant 190 is a flexible EMC, such as polyimide, thermoplastic elastomer, thermoplastic vulcanizate, thermoplastic urethane, polyvinyl chloride, and other suitable flexible material. Flexible encapsulant 190 can be liquid or granular polymer composite material, such as a flexible resin with filler, flexible epoxy with filler, or flexible polymer with proper filler. Flexible encapsulant 190 is non-conductive, provides structural support, and environmentally protects the semiconductor device from external elements and contaminants.

In FIG. 4d, carrier 180 is removed by releasing adhesive film 184 with heat or UV light, leaving active surface 121 of electrical components 174a-174c exposed for electrical interconnect.

In FIG. 4e, insulating or passivation layer 192 is formed over conductive layer 122 and active surface 121 of electrical components 174a-174c using PVD, CVD, printing, lamination, spin coating, spray coating, sintering or thermal oxidation. Insulating layer 192 contains one or more layers of SiO2, Si3N4, SiON, Ta2O5, Al2O3, solder resist, polyimide, BCB, PBO, and other material having similar insulating and structural properties. Portions of insulating layer 192 are removed using an etching process or LDA to form openings or vias extending to conductive layer 122 for further electrical interconnect.

A conductive layer 194 is formed over insulating layer 192 using PVD, CVD, electrolytic plating, electroless plating process, or other suitable metal deposition process. Conductive layer 194 can be one or more layers of Al, Cu, Sn, Ni, Au, Ag, or other suitable electrically conductive material. Portions of conductive layer 194 can be electrically common or electrically isolated depending on the design and function of electrical components attached thereto. Conductive layer 194 operates as an RDL as it redistributes the electrical signal across and over electrical components 174a-174c and flexible encapsulant 190.

In FIG. 4f, an electrically conductive bump material is deposited over conductive layer 194 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 194 using a suitable attachment or bonding process. In one embodiment, the bump material is reflowed by heating the material above its melting point to form balls or bumps 196. In one embodiment, bump 196 is formed over a UBM having a wetting layer, barrier layer, and adhesive layer. Bump 196 can also be compression bonded or thermocompression bonded to conductive layer 194. Bump 196 represents one type of interconnect structure that can be formed over conductive layer 194. The interconnect structure can also use bond wires, conductive paste, stud bump, micro bump, or other electrical interconnect.

The combination of insulating layer 192, conductive layer 194, and bumps 196 constitute interconnect structure 198. Additional insulating layers like 192 and conductive layers like 194 can be formed as well to interconnect structure 198. The combination of electrical components 174a-174c, interconnect structure 198, and flexible encapsulant 190 constitute semiconductor package 200.

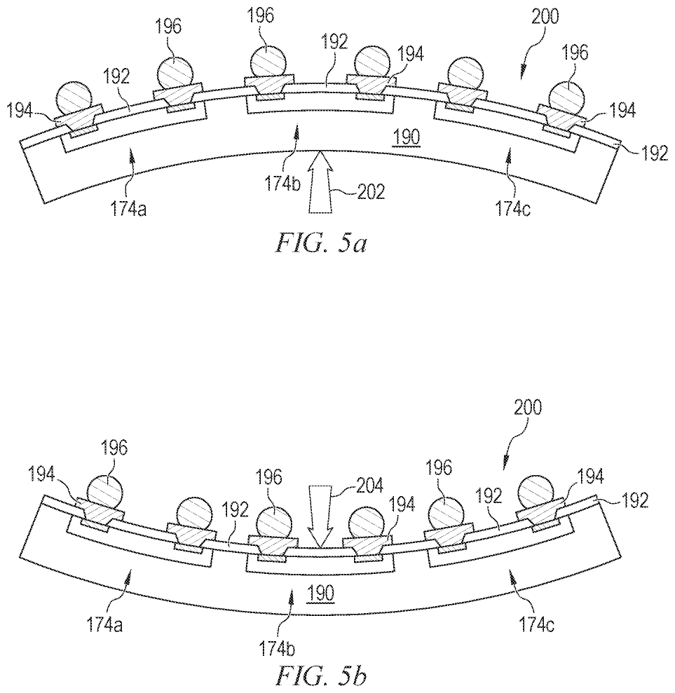

The flexible nature of encapsulant 190 allows semiconductor package 200 to bend and flex, as shown in FIGS. 5a-5b. As noted above, electrical components 174a-174c are thin and flexible. Flexible encapsulant 190 helps protect the thin and flexible electrical components 174a-174c. Semiconductor package 200 is convex in response to a force in the direction of arrow 202, as in FIG. 5a. Semiconductor package 200 is concave in response to a force in the direction of arrow 204, as in FIG. 5b. Semiconductor package 200 is light weight, and the thin and flexible electrical components 174a-174c are efficient controlling of heat and electrical generation. Semiconductor package 200 is applicable to wearable devices, e.g., flexible displays.

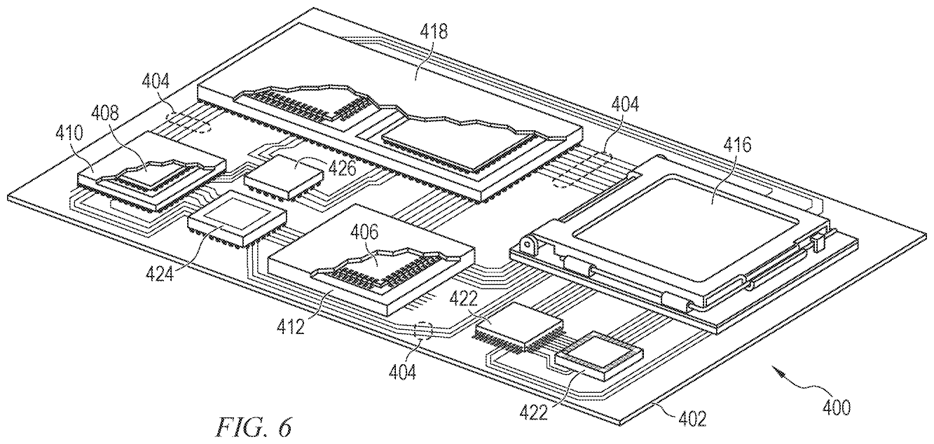

FIG. 6 illustrates electrical device 400 having a chip carrier substrate or PCB 402 with a plurality of semiconductor packages disposed on a surface of PCB 402, including semiconductor packages 162 and 200. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first electrical component;
a flexible encapsulant disposed over the first electrical component; and
an interconnect structure formed over the first electrical component.

2. The semiconductor device of claim 1, wherein the first electrical component includes a thickness of 400 micrometers.

3. The semiconductor device of claim 1, wherein the flexible encapsulant includes a material selected from the group consisting of polyimide, thermoplastic elastomer, thermoplastic vulcanizate, thermoplastic urethane, and polyvinyl chloride.

4. The semiconductor device of claim 1, wherein the interconnect structure includes:
an insulating layer formed over the first electrical component; and
a conductive layer formed over the insulating layer.

5. The semiconductor device of claim 1, further including a second electrical component, wherein the flexible encapsulant is disposed over the second electrical component.

6. The semiconductor device of claim 5, wherein the second electrical component has a different electrical function from the first electrical component.

7. A semiconductor device, comprising:
a first thin electrical component; and
a flexible encapsulant disposed over the first thin electrical component.

8. The semiconductor device of claim 7, wherein the first thin electrical component includes a thickness of 400 micrometers.

9. The semiconductor device of claim 7, wherein the flexible encapsulant includes a material selected from the group consisting of polyimide, thermoplastic elastomer, thermoplastic vulcanizate, thermoplastic urethane, and polyvinyl chloride.

10. The semiconductor device of claim 7, further including an interconnect structure formed over the first thin electrical component.

11. The semiconductor device of claim 10, wherein the interconnect structure includes:
an insulating layer formed over the first thin electrical component; and
a conductive layer formed over the insulating layer.

12. The semiconductor device of claim 7, further including a second thin electrical component, wherein the flexible encapsulant is disposed over the second thin electrical component.

13. The semiconductor device of claim 12, wherein the second thin electrical component has a different electrical function from the first thin electrical component.

14. A method of making a semiconductor device, comprising:
providing a first electrical component;
disposing a flexible encapsulant over the first electrical component; and
forming an interconnect structure over the first electrical component.

15. The method of claim 14, wherein the first electrical component includes a thickness of 400 micrometers.

16. The method of claim 14, wherein the flexible encapsulant includes a material selected from the group consisting of polyimide, thermoplastic elastomer, thermoplastic vulcanizate, thermoplastic urethane, and polyvinyl chloride.

17. The method of claim 14, wherein forming the interconnect structure includes:
forming an insulating layer over the first electrical component; and
forming a conductive layer over the insulating layer.

18. The method of claim 14, further including providing a second electrical component, wherein the flexible encapsulant is disposed over the second electrical component.

19. The method of claim 18, wherein the second electrical component has a different electrical function from the first electrical component.

20. A method of making a semiconductor device, comprising:
providing a first thin electrical component; and
disposing a flexible encapsulant over the first thin electrical component.

21. The method of claim 20, wherein the first thin electrical component includes a thickness of 400 micrometers.

22. The method of claim 20, wherein the flexible encapsulant includes a material selected from the group consisting of polyimide, thermoplastic elastomer, thermoplastic vulcanizate, thermoplastic urethane, and polyvinyl chloride.

23. The method of claim 20, further including forming an interconnect structure over the first thin electrical component.

24. The method of claim 20, further including providing a second thin electrical component, wherein the flexible encapsulant is disposed over the second thin electrical component.

25. The method of claim 24, wherein the second thin electrical component has a different electrical function from the first thin electrical component.
